(19) United States
(12) Patent Application Publication
(10) Pub. No.: US 2023/0146964 A1
(43) Pub. Date: May 11, 2023

(54) PHOTOVOLTAIC CELL DEVICE

(71) Applicants: Japan Display Inc., Tokyo (JP); OSAKA UNIVERSITY, Osaka (JP)

(72) Inventors: Shinichiro OKA, Tokyo (JP); Yasushi TOMIOKA, Tokyo (JP); Junji KOBASHI, Tokyo (JP); Hiroyuki YOSHIDA, Suita-shi (JP)

(73) Assignees: Japan Display Inc., Tokyo (JP); OSAKA UNIVERSITY, Osaka (JP)

(21) Appl. No.: 18/091,384

(22) Filed: Dec. 30, 2022

Related U.S. Application Data
(63) Continuation of application No. PCT/JP2021/024609, filed on Jun. 29, 2021.

(30) Foreign Application Priority Data
Jul. 13, 2020 (JP) 2020-119969

(51) Int. Cl. H01L 31/054; G02F 1/133; G02F 1/137

(52) U.S. Cl. CPC H01L 31/0547; G02F 1/13324; G02F 1/13718

(57) ABSTRACT

According to one embodiment, a photovoltaic cell device includes an optical waveguide, an optical element, and a photovoltaic cell. The optical element includes a first liquid crystal layer which contains a cholesteric liquid crystal, reflects, of visible light, circularly polarized light of one of first circularly polarized light and second circularly polarized light rotating in an opposite direction of the first circularly polarized light toward the optical waveguide and the photovoltaic cell, and transmits the other circularly polarized light. The first liquid crystal layer reflects one of the first circularly polarized light and the second circularly polarized light of part of wavelength ranges.

### CROSS-REFERENCE TO RELATED APPLICATIONS

This application is a Continuation Application of PCT Application No. PCT/JP2021/024609, filed Jun. 29, 2021 and based upon and claiming the benefit of priority from Japanese Patent Application No. 2020-119969, filed Jul. 13, 2020, the entire contents of all of which are incorporated herein by reference.

### FIELD

Embodiments described herein relate generally to a photovoltaic cell device.

### BACKGROUND

Recently, various types of transparent photovoltaic cells have been suggested. For example, a display device comprising a transparent dye-sensitized photovoltaic cell on the surface of the display device has been suggested. Although the dye-sensitized photovoltaic cell transmits part of visible light, a constituent material of the cell absorbs some wavelength ranges. Thus, there is a problem in which transmitted light is colored.

### BRIEF DESCRIPTION OF THE DRAWINGS

FIG. 1 is a cross-sectional view schematically showing a photovoltaic cell device 100 according to embodiment 1.

FIG. 2 is a cross-sectional view schematically showing the structure of an optical element 3.

FIG. 3 is a plan view schematically showing the photovoltaic cell device 100.

FIG. 4 is a cross-sectional view schematically showing an example of a first liquid crystal layer 31 constituting the optical element 3.

FIG. 5 is a cross-sectional view schematically showing the optical element 3 according to a modified example of embodiment 1.

FIG. 6 is a cross-sectional view schematically showing a photovoltaic cell device 100 according to embodiment 2.

FIG. 7 is a cross-sectional view schematically showing a photovoltaic cell device 100 according to embodiment 3.

FIG. 8 is a cross-sectional view schematically showing an optical element 3 according to a modified example of embodiment 3.

FIG. 9 is a plan view schematically showing a photovoltaic cell device 100 according to embodiment 4.

FIG. 10 is a cross-sectional view schematically showing the photovoltaic cell device 100 according to embodiment 4.

FIG. 11A is a plan view schematically showing an example of the infrared reflective layer RI which can be combined with a first photovoltaic cell 51 according to embodiment 4.

FIG. 11B is a plan view schematically showing an example of an ultraviolet reflective layer RU which can be combined with a second photovoltaic cell 52 according to embodiment 4.

FIG. 12 is a plan view schematically showing a photovoltaic cell device 100 according to embodiment 5.

FIG. 13 is a cross-sectional view schematically showing the photovoltaic cell device 100 according to embodiment 5.

FIG. 14 is a plan view schematically showing a photovoltaic cell device 100 according to embodiment 6.

FIG. 15 is a cross-sectional view schematically showing the photovoltaic cell device 100 according to embodiment 6.

FIG. 16 is a plan view schematically showing the photovoltaic cell device 100 according to modified example 1 of embodiment 6.

FIG. 17 is a plan view schematically showing the photovoltaic cell device 100 according to modified example 2 of embodiment 6.

### DETAILED DESCRIPTION

In general, according to one embodiment, a photovoltaic cell device comprises an optical waveguide comprising a first main surface, a second main surface facing the first main surface, and a side surface, an optical element facing the second main surface, and a photovoltaic cell facing the side surface. The optical element comprises a first liquid crystal layer which comprises a cholesteric liquid crystal, reflects, of visible light incident on the first main surface, circularly polarized light of one of first circularly polarized light and second circularly polarized light rotating in an opposite direction of the first circularly polarized light toward the optical waveguide and the photovoltaic cell, and transmits the other circularly polarized light. The visible light includes a plurality of wavelength ranges. The first liquid crystal layer reflects one of the first circularly polarized light and the second circularly polarized light of part of the wavelength ranges.

According to another embodiment, a photovoltaic cell device comprises an optical waveguide comprising a first main surface, a second main surface facing the first main surface, and a side surface, an optical element facing the second main surface, and a first photovoltaic cell facing the side surface and comprising polycrystalline silicon. The optical element comprises an infrared reflective layer which comprises a cholesteric liquid crystal and reflects, of infrared light incident on the first main surface, at least one of first circularly polarized light and second circularly polarized light rotating in an opposite direction of the first circularly polarized light toward the optical waveguide and the first photovoltaic cell.

Embodiments described herein can provide a photovoltaic cell device which can generate electricity without coloring.

Embodiments will be described hereinafter with reference to the accompanying drawings. The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the Z-axis is referred to as a first direction A1. A direction parallel to the Y-axis is referred to as a second direction A2. A direction parallel to the X-axis is referred to as a third direction A3. The first direction A1, the second direction A2 and the third direction A3 are orthogonal to each other. The plane defined by the X-axis and the Y-axis is referred to as an X-Y plane. The plane defined by the X-axis and the Z-axis is referred to as an X-Z plane. The plane defined by the Y-axis and the Z-axis is referred to as a Y-Z plane.

### Embodiment 1

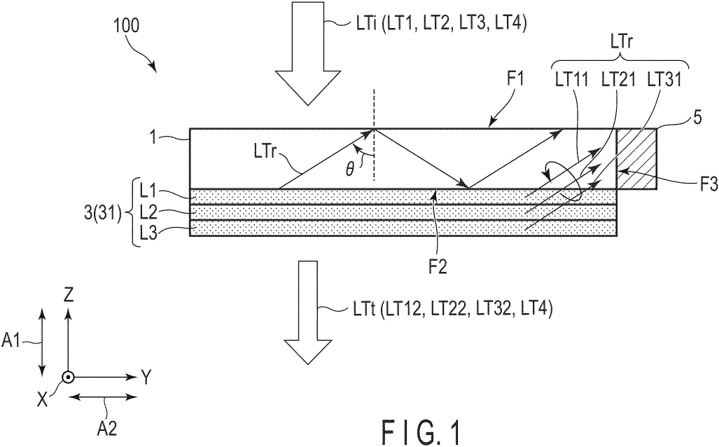

FIG. 1 is a cross-sectional view schematically showing a photovoltaic cell device 100 according to embodiment 1. The photovoltaic cell device 100 comprises an optical waveguide 1, an optical element 3 and a photovoltaic cell 5.

The optical waveguide 1 consists of a transparent member which transmits light, for example, a transparent glass plate or a transparent synthetic resinous plate. For example, the optical waveguide 1 may consist of a transparent synthetic resinous plate having flexibility. The optical waveguide 1 could have an arbitrary shape. For example, the optical waveguide 1 may be curved. For example, the refractive index of the optical waveguide 1 is greater than that of air. The optical waveguide 1 functions as, for example, window glass.

In this specification, the term “light” includes visible light and invisible light. For example, the wavelength of the lower limit of a visible light range is greater than or equal to 360 nm but less than or equal to 400 nm. The wavelength of the upper limit of a visible light range is greater than or equal to 760 nm but less than or equal to 830 nm. Visible light includes the first component (blue component) LT1 of a first wavelength range (for example, 400 to 500 nm), the second component (green component) LT2 of a second wavelength range (for example, 500 to 600 nm), and the third component (red component) LT3 of a third wavelength range (for example, 600 to 700 nm). Invisible light LT4 includes ultraviolet light having a wavelength range in which the wavelength is shorter than the first wavelength range, and infrared light having a wavelength range in which the wavelength is longer than the third wavelength range.

In this specification, the term “transparent” should preferably mean “colorless and transparent”. However, the term “transparent” may mean “semitransparent” or “colored and transparent”.

The optical waveguide 1 is shaped like a flat plate parallel to an X-Y plane and comprises a first main surface F1, a second main surface F2 and a side surface F3. The first main surface F1 and the second main surface F2 are surfaces substantially parallel to the X-Y plane and face each other in a first direction A1. The side surface F3 is a surface extending in the first direction A1. In the example shown in FIG. 1, the side surface F3 is a surface substantially parallel to an X-Z plane. The side surface F3 includes a surface substantially parallel to a Y-Z plane.

The optical element 3 faces the second main surface F2 of the optical waveguide 1 in the first direction A1. The optical element 3 reflects at least part of the light LTi which entered the first main surface F1 toward the optical waveguide 1. For example, the optical element 3 comprises a first liquid crystal layer 31 which reflects, of the incident light LTi, at least one of first circularly polarized light and second circularly polarized light which rotates in the opposite direction of the first circularly polarized light. Each of the first circularly polarized light and the second circularly polarized light includes the first component LT1, the second component LT2 and the third component LT3 described above. In this specification, reflection in the optical element 3 is accompanied by diffraction inside the optical element 3.

It should be noted that, for example, the optical element 3 may have flexibility. Further, the optical element 3 may be in contact with the second main surface F2 of the optical waveguide 1. Alternatively, a transparent layer such as an adhesive layer may be interposed between the optical element 3 and the optical waveguide 1. It is preferable that the refractive index of the layer interposed between the optical element 3 and the optical waveguide 1 should be substantially equal to that of the optical waveguide 1. The optical element 3 is configured as, for example, a film.

In embodiment 1, the first liquid crystal layer 31 comprises a first layer L1, a second layer L2 and a third layer L3. In the example of FIG. 1, the first layer L1, the second layer L2 and the third layer L3 are stacked in this order in the first direction A1. The first layer L1 faces the second main surface F2. It should be noted that the order in which the first layer L1, the second layer L2 and the third layer L3 are stacked is not limited to the example shown in FIG. 1.

For example, each of the first layer L1, the second layer L2 and the third layer L3 is a liquid crystal layer configured to reflect the first circularly polarized light and transmit the second circularly polarized light which rotates in the opposite direction of the first circularly polarized light. The first layer L1 is a layer which mainly reflects, of the first component LT1, the first component LT11 of the first circularly polarized light. The second layer L2 is a layer which mainly reflects, of the second component LT2, the second component LT21 of the first circularly polarized light. The third layer L3 is a layer which mainly reflects, of the third component LT3, the third component LT31 of the first circularly polarized light.

The photovoltaic cell 5 faces the side surface F3 of the optical waveguide 1 in a second direction A2. The photovoltaic cell 5 receives light and converts the energy of the received light into electricity. Thus, the photovoltaic cell 5 generates electricity by the received light. The type of the photovoltaic cell is not particularly limited. The photovoltaic cell 5 is, for example, a silicon-based photovoltaic cell, a compound-based photovoltaic cell, an organic photovoltaic cell, a perovskite photovoltaic cell or a quantum dot photovoltaic cell. The silicon-based photovoltaic cell includes a photovoltaic cell comprising amorphous silicon, a photovoltaic cell comprising polycrystalline silicon, etc.

The photovoltaic cell 5 is directly or indirectly connected to the optical waveguide 1. For example, the photovoltaic cell 5 is directly or indirectly connected to the side surface F3 of the optical waveguide 1. When the photovoltaic cell 5 is indirectly connected to the side surface F3 of the optical waveguide 1, for example, a transparent layer or an optical component (lens, etc.,) is interposed between the photovoltaic cell 5 and the side surface F3 of the optical waveguide 1.

Now, in embodiment 1 of FIG. 1, the operation of the photovoltaic cell device 100 is explained.

The light LTi which enters the first main surface F1 of the optical waveguide 1 is, for example, solar light. Light LTi includes invisible light LT4 in addition to the first, second and third components LT1, LT2 and LT3 of visible light.

In the example of FIG. 1, in order to facilitate understanding, light LTi is assumed to enter the optical waveguide 1 so as to be substantially perpendicular to the optical waveguide 1. It should be noted that the incident angle of light LTi with respect to the optical waveguide 1 is not particularly limited. For example, light LTi may enter the optical waveguide 1 at a plurality of incident angles different from each other.

Light LTi proceeds into the optical waveguide 1 through the first main surface F1 and enters the optical element 3 via the second main surface F2. The optical element 3 reflects light LTr which is part of light LTi toward the optical waveguide 1 and the photovoltaic cell 5 and transmits the other light LTt. Here, a light loss such as absorption in the optical waveguide 1 and the optical element 3 is ignored. In embodiment 1, the light LTr reflected on the optical element 3 is equivalent to the first circularly polarized light of visible light. The light LTt which passes through the optical element 3 includes the second circularly polarized light of visible light. In this specification, circularly polarized light may be strict circularly polarized light or may be circularly polarized light which approximates elliptically polarized light.

More specifically, in the optical element 3, the first layer L1 reflects the first component LT11 of the first circularly polarized light, and transmits the first component LT12 of the second circularly polarized light, and in addition, transmits the second component LT2, the third component LT3 and invisible light LT4.

The second layer L2 reflects the second component LT21 of the first circularly polarized light, and transmits the first and second components LT12 and LT22 of the second circularly polarized light, and in addition, transmits the third component LT3 and invisible light LT4.

The third layer L3 reflects the third component LT31 of the first circularly polarized light, and transmits the first, second and third components LT12, LT22 and LT32 of the second circularly polarized light, and in addition, transmits invisible light LT4.

Thus, the light LTr reflected on the optical element 3 includes the first, second and third components LT11, LT21 and LT31 of the first circularly polarized light. The optical element 3 reflects each of the first component LT11, the second component LT21 and the third component LT31 toward the optical waveguide 1 at an entering angle θwhich satisfies the optical waveguide conditions in the optical waveguide 1. Here, the entering angle θ is equivalent to an angle greater than or equal to a critical angle θc which causes total reflection inside the optical waveguide 1. The entering angle θ indicates an angle with respect to a perpendicular line orthogonal to the optical waveguide 1.

Light LTr proceeds into the optical waveguide 1 through the second main surface F2 and propagates inside the optical waveguide 1 while repeating reflection in the optical waveguide 1.

The photovoltaic cell 5 receives the light LTr emitted from the side surface F3 and generates electricity.

The light LTt which passes through the optical element 3 includes the first, second and third components LT12, LT22 and LT32 of the second circularly polarized light and invisible light LT4.

According to this embodiment 1, the optical element 3 reflects approximately 50% of circularly polarized light toward the photovoltaic cell 5 with respect to each of the first (blue), second (green) and third (red) components which are the main components of visible light, and transmits the other approximately 50% of circularly polarized light. In this way, approximately 50% of visible light can be used for electric generation, and the coloring of the light which passes through the photovoltaic cell device 100 can be prevented.

Further, the light of substantially the entire wavelength range of visible light can be introduced into the photovoltaic cell 5, and the amount of the received light of the photovoltaic cell 5 per unit time can be increased. In this way, the electric generation efficiency of the photovoltaic cell 5 can be improved.

The above embodiment 1 is explained regarding the example in which each of the first layer L1, the second layer L2 and the third layer L3 reflects the first circularly polarized light and transmits the second circularly polarized light. However, the configuration is not limited to this example. Each of the first layer L1, the second layer L2 and the third layer L3 may reflect one of the first circularly polarized light and the second circularly polarized light and transmit the other.

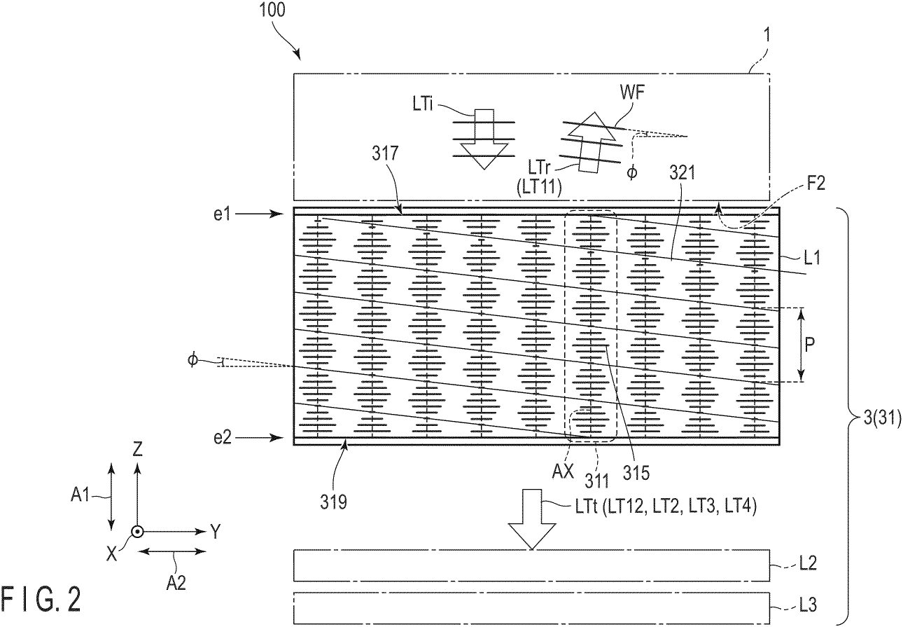

FIG. 2 is a cross-sectional view schematically showing the structure of the optical element 3. Here, as a representative of the first to third layers of the first liquid crystal layer 31 constituting the optical element 3, the first layer L1 is shown. It should be noted that the second layer L2 and the third layer L3 are configured in the same manner as the first layer L1. The second layer L2 and the third layer L3 are shown by alternate long and short dash lines. The optical waveguide 1 is shown by alternate long and two short dashes lines.

The optical element 3 comprises a plurality of helical structures 311. Each of the helical structures 311 extends in the first direction A1. In other words, the helical axis AX of each of the helical structures 311 is substantially perpendicular to the second main surface F2 of the optical waveguide 1. The helical axis AX is substantially parallel to the first direction A1. Each of the helical structures 311 has a helical pitch P. The helical pitch P indicates one pitch (360 degrees) of the helix. Each of the helical structures 311 includes a plurality of elements 315. The elements 315 are helically stacked in the first direction A1 while twisting.

The optical element 3 comprises a first interface 317 facing the second main surface F2, a second interface 319 on the opposite side of the first interface 317, and a plurality of reflective surfaces 321 between the first interface 317 and the second interface 319. The light LTi emitted from the second main surface F2 after passing through the optical waveguide 1 enters the first interface 317. Each of the first interface 317 and the second interface 319 is substantially perpendicular to the helical axis AX of each helical structure 311. Each of the first interface 317 and the second interface 319 is substantially parallel to the optical waveguide 1 (or the second main surface F2).

The first interface 317 includes the element 315 which is located in an end portion e1 of the both end portions of each helical structure 311. The first interface 317 is located in the boundary between the optical waveguide 1 and the first layer L1 of the optical element 3. The second interface 319 includes the element 315 which is located in the other end portion e2 of the both end portions of each helical structure 311. The second interface 319 is located in the boundary between the first layer L1 of the optical element 3 and the second layer L2.

In embodiment 1, the reflective surfaces 321 are substantially parallel to each other. Each reflective surface 321 inclines with respect to the first interface 317 and the optical waveguide 1 (or the second main surface F2) and has substantially a plane shape extending in a certain direction. Each reflective surface 321 applies selective reflection to light LTr of the light LTi which entered the first interface 317 in accordance with the Bragg’s law. Specifically, each reflective surface 321 reflects light LTr such that the wavefront WF of light LTr is substantially parallel to the reflective surface 321. More specifically, each reflective surface 321 reflects light LTr based on the inclination angle φof the reflective surface 321 with respect to the first interface 317.

The reflective surfaces 321 can be defined as follows. The refractive index sensed by the light (for example, circularly polarized light) which is selectively reflected in the optical element 3 and has a predetermined wavelength gradually changes as the light travels inside the optical element 3. Thus, the Fresnel reflection gradually occurs in the optical element 3. In the helical structures 311, a position at which the change in the refractive index sensed by light is the largest exhibits the strongest Fresnel reflection. In other words, each reflective surface 321 is equivalent to a surface which exhibits the strongest Fresnel reflection in the optical element 3.

Of the helical structures 311, the alignment directions of the elements 315 of the helical structures 311 which are adjacent to each other in the second direction A2 are different from each other. Further, of the helical structures 311, the spacial phases of the helical structures 311 which are adjacent to each other in the second direction A2 are different from each other. Each reflective surface 321 is equivalent to a surface in which the alignment directions of the elements 315 are uniform, or a surface in which spacial phases are uniform. In other words, each of the reflective surfaces 321 inclines with respect to the first interface 317 or the optical waveguide 1.

It should be noted that the shape of each reflective surface 321 is not limited to the plane shape shown in FIG. 2, and may be a curved shape such as a concave shape or a convex shape, and thus, is not particularly limited. Part of each reflective surface 321 may be uneven. The inclination angles φof the reflective surfaces 321 may not be uniform. The reflective surfaces 321 may not be regularly aligned. The reflective surfaces 321 may be configured to have arbitrary shapes based on the distribution of the spacial phases of the helical structures 311.

In the present embodiment, the helical structures 311 are cholesteric liquid crystals. Each of the elements 315 is equivalent to a liquid crystal molecule. In FIG. 2, in order to simplify the figure, each element 315 shows a liquid crystal molecule which faces an average alignment direction as a representative of the liquid crystal molecules located in the X-Y plane.

Cholesteric liquid crystals which are the helical structures 311 reflect circularly polarized light which is light having a predetermined wavelength λ included in a selective reflection range Δλ and which rotates in the same rotation direction as the twist directions of the helices of the cholesteric liquid crystals. For example, when the twist direction of the cholesteric liquid crystal is right-handed, of the light having the predetermined wavelength λ, the cholesteric liquid crystal reflects right-handed circularly polarized light and transmits left-handed circularly polarized light. Similarly, when the twist direction of the cholesteric liquid crystal is left-handed, of the light having the predetermined wavelength λ, the cholesteric liquid crystal reflects left-handed circularly polarized light and transmits right-handed circularly polarized light.

In FIG. 2, the light LTr reflected by the helical structures 311 of the first layer L1 is the first component LT11 of the first circularly polarized light. The light LTt which passes through the first layer L1 includes the first component LT12 of the second circularly polarized light, and in addition, the second and third components LT2 and LT3 of visible light and invisible light LT4.

When the pitch of the helix of cholesteric liquid crystals is defined as P, and the refractive index of liquid crystal molecules with respect to extraordinary light is defined as ne, and the refractive index of liquid crystal molecules with respect to ordinary light is defined as no, in general, the selective reflection range Δλ of cholesteric liquid crystals with respect to normal incident light is shown by “no*P to ne*P”. Specifically, the selective reflection range Δλ of cholesteric liquid crystals changes based on the inclination angle φ of the reflective surfaces 321, the incident angle on the first interface 317, etc., with respect to the range “no*P to ne*P”.

In the first layer L1 shown in FIG. 2, the helical pitch P of the helical structures 311 and refractive indices ne and no of liquid crystal molecules as the elements 315 are set so as to reflect the first component LT1. Similarly, in the second layer L2, the helical pitch P and refractive indices ne and no are set so as to reflect the second component LT2. Similarly, in the third layer L3, the helical pitch P and refractive indices ne and no are set so as to reflect the third component LT3. In some cases, the helical pitch of the first layer L1 is called a first helical pitch P1, and the helical pitch of the second layer L2 is called a second helical pitch P2, and the helical pitch of the third layer L3 is called a third helical pitch P3. When the first layer L1, the second layer L2 and the third layer L3 consist of the same elements 315, the first helical pitch P1, the second helical pitch P2 and the third helical pitch P3 are different from each other.

When the optical element 3 consists of cholesteric liquid crystals, for example, the optical element 3 is formed as a film. The optical element 3 as a film is formed by, for example, polymerizing a plurality of helical structures 311. Specifically, the optical element 3 as a film is formed by polymerizing the elements (liquid crystal molecules) 315 contained in the optical element 3. For example, a plurality of liquid crystal molecules are polymerized by emitting light to the liquid crystal molecules.

Alternatively, the optical element 3 as a film is formed by, for example, controlling the alignment of polymer liquid crystal materials showing a liquid crystalline state at a predetermined temperature or a predetermined concentration so as to form a plurality of helical structures 311 in a liquid crystalline state and subsequently causing them to transition to a solid while maintaining the alignment.

By polymerization or transition to a solid, in the optical element 3 as a film, adjacent helical structures 311 are bound together while maintaining the alignment of the helical structures 311, in other words, while maintaining the spacial phases of the helical structures 311. As a result, in the optical element 3 as a film, the alignment direction of each liquid crystal molecule is fixed.

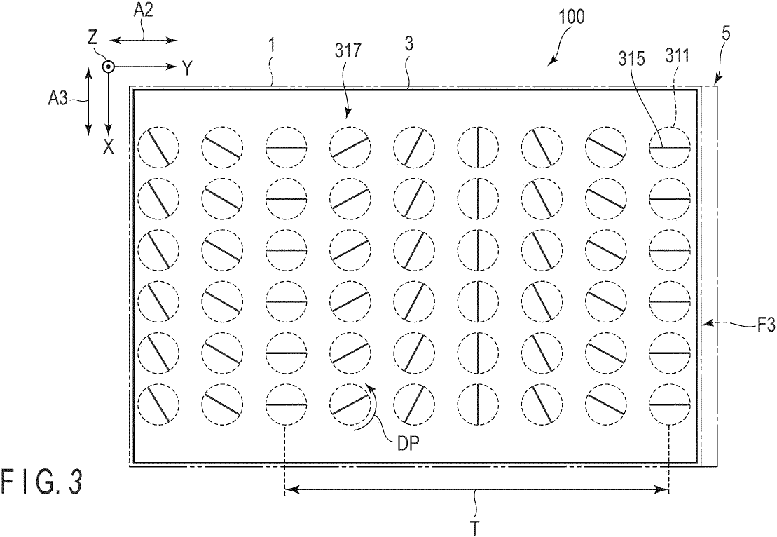

FIG. 3 is a plan view schematically showing the photovoltaic cell device 100. In FIG. 3, the optical waveguide 1 is shown by alternate long and two short dashes lines, and the optical element 3 are shown by solid lines, and the helical structures 311 are shown by dotted lines, and the photovoltaic cell 5 is shown by alternate long and short dash lines.

FIG. 3 shows an example of the spacial phases of the helical structures 311. Here, the spacial phases are shown as the alignment directions of, of the elements 315 contained in the helical structures 311, the elements 315 located at the first interface 317.

Regarding the helical structures 311 arranged in the second direction A2, the alignment directions of the elements 315 located at the first interface 317 are different from each other. In other words, the spacial phases of the helical structures 311 at the first interface 317 differ in the second direction A2.

To the contrary, regarding the helical structures 311 arranged in a third direction A3, the alignment directions of the elements 315 located at the first interface 317 are substantially coincident with each other. In other words, the spacial phases of the helical structures 311 at the first interface 317 are substantially coincident with each other in the third direction A3.

In particular, regarding the helical structures 311 arranged in the second direction A2, the alignment direction varies with each element 315 by a certain degree. In other words, at the first interface 317, the alignment direction linearly varies with the elements 315 arranged in the second direction A2. Thus, the spacial phase linearly varies with the helical structures 311 arranged in the second direction A2. As a result, like the optical element 3 shown in FIG. 2, the reflective surfaces 321 which incline with respect to the first interface 317 and the optical waveguide 1 are formed. Here, the phrase “linearly vary” means that, for example, the amount of variation in the alignment directions of the elements 315 is shown by a linear function.

Here, as shown in FIG. 3, the interval between two helical structures 311 when the alignment directions of the elements 315 vary by 180 degrees in the second direction A2 at the first interface 317 is defined as pitch T of the helical structures 311. In FIG. 3, DP indicates the twist direction of each element. The inclination angle φ of each reflective surface 321 shown in FIG. 2 is arbitrarily set based on pitch T and the helical pitch P.

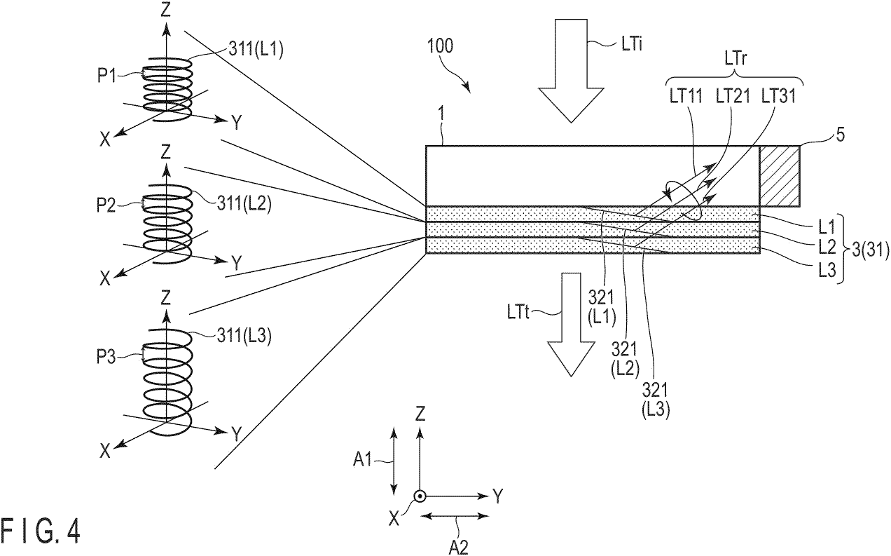

FIG. 4 is a cross-sectional view schematically showing an example of the first liquid crystal layer 31 constituting the optical element 3. Here, as the helical structures 311 in the first layer L1, the second layer L2 and the third layer L3, cholesteric liquid crystals which twist in a single direction are schematically shown. The helical structures 311 in the first layer L1, the second layer L2 and the third layer L3 twist in the same direction, and are configured to, for example, reflect the first circularly polarized light.

In the first layer L1, the helical structure 311 comprises the first helical pitch P1 so as to reflect the first component LT11 of the first circularly polarized light.

In the second layer L2, the helical structure 311 comprises the second helical pitch P2 so as to reflect the second component LT21 of the first circularly polarized light. The second helical pitch P2 is different from the first helical pitch P1.

In the third layer L3, the helical structure 311 comprises the third helical pitch P3 so as to reflect the third component LT31 of the first circularly polarized light. The third helical pitch P3 is different from the first helical pitch P1 and the second helical pitch P2.

The second helical pitch P2 is greater than the first helical pitch P1, and the third helical pitch P3 is greater than the second helical pitch P2 (P1 < P2 < P3) .

It should be noted that, the helical structures 311 of one of the layers may twist in a direction different from the helical structures 311 of the other layers. In this case, circularly polarized light rays in opposite directions are reflected.

In embodiment 1, the first layer L1, the second layer L2 and the third layer L3 are individually formed. In the first layer L1, the first helical pitch P1 of the helical structures 311 undergoes very little change and is constant. Similarly, in the second layer L2, the second helical pitch P2 is almost constant, and further, in the third layer L3, the third helical pitch P3 is almost constant.

### Modified Example

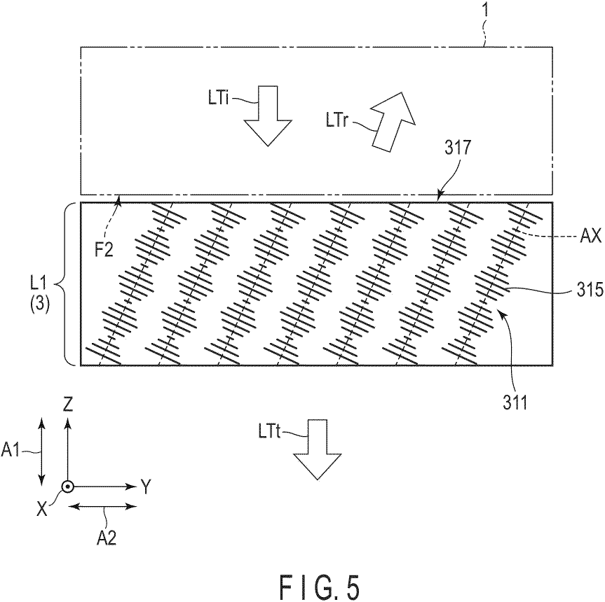

FIG. 5 is a cross-sectional view schematically showing the optical element 3 according to a modified example of embodiment 1. Here, as a representative of the first to third layers of the first liquid crystal layer 31 constituting the optical element 3, the first layer L1 is shown. It should be noted that the second layer L2 and the third layer L3 are configured in the same manner as the first layer L1.

The modified example shown in FIG. 5 is different from the above embodiment 1 in respect that the helical axis AX of each helical structure 311 inclines with respect to the optical waveguide 1 or the second main surface F2. In the modified example here, the spacial phases of the helical structures 311 at the first interface 317 or the X-Y plane are substantially coincident with each other. The other properties of the helical structures 311 of the modified example are the same as the helical structures 311 of embodiment 1.

In this modified example, the optical element 3 reflects light LTr which is part of the incident light LTi through the optical waveguide 1 at a reflective angle based on the inclination of the helical axis AX, and transmits the other light LTt.

In this modified example, effects similar to those of the above embodiment 1 are obtained.

### Embodiment 2

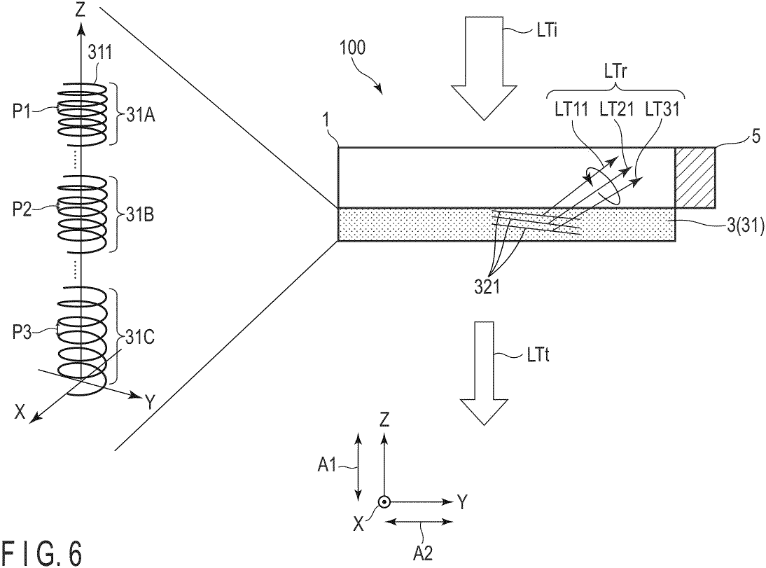

FIG. 6 is a cross-sectional view schematically showing a photovoltaic cell device 100 according to embodiment 2. The embodiment 2 shown in FIG. 6 is different from the above embodiment 1 in respect that a first liquid crystal layer 31 constituting an optical element 3 is a single-layer body. Here, as a helical structure 311 in the first liquid crystal layer 31, a cholesteric liquid crystal which twists in a single direction is schematically shown.

In the first liquid crystal layer 31, the helical pitch P of the helical structure 311 continuously changes in a first direction A1. The helical structure 311 comprises a first portion 31A comprising a first helical pitch P1 for reflecting a first component LT11, a second portion 31B comprising a second helical pitch P2 for reflecting a second component LT21, and a third portion 31C comprising a third helical pitch P3 for reflecting a third component LT31. In other words, each of the first portion 31A, the second portion 31B and the third portion 31C is part of the helical structure 311 which twists in the same direction.

The second helical pitch P2 is greater than the first helical pitch P1, and the third helical pitch P3 is greater than the second helical pitch P2 (P1 < P2 < P3) .

In this embodiment 2, effects similar to those of embodiment 1 are obtained.

### Embodiment 3

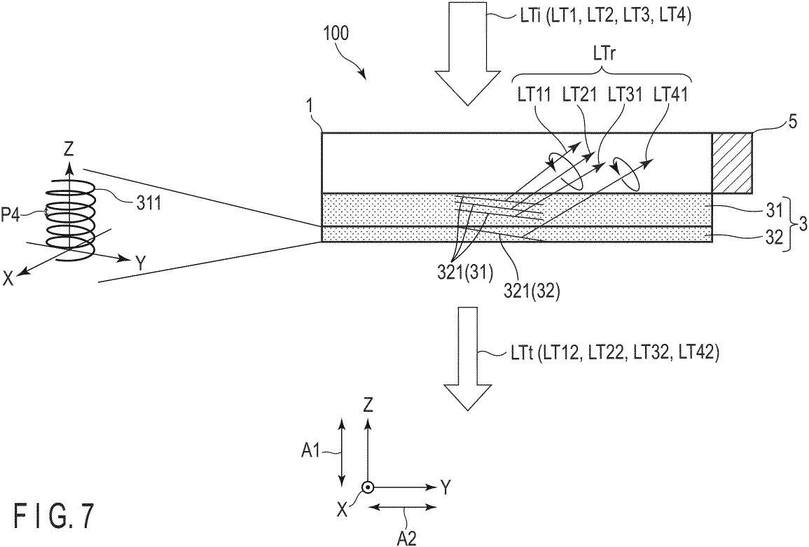

FIG. 7 is a cross-sectional view schematically showing a photovoltaic cell device 100 according to embodiment 3. The embodiment 3 shown in FIG. 7 is different from the above embodiment 2 in respect that an optical element 3 comprises a second liquid crystal layer 32 overlapping a first liquid crystal layer 31. In the example shown in FIG. 7, the first liquid crystal layer 31 is provided between an optical waveguide 1 and the second liquid crystal layer 32. However, the second liquid crystal layer 32 may be provided between the optical waveguide 1 and the first liquid crystal layer 31. It should be noted that the first liquid crystal layer 31 may be a single-layer body like embodiment 2 or may be a stacked layer body of a plurality of layers like embodiment 1.

The second liquid crystal layer 32 comprises cholesteric liquid crystals which twist in a single direction as helical structures 311 in the same manner as the first liquid crystal layer 31. Here, a cholesteric liquid crystal in the second liquid crystal layer 32 is schematically shown. The second liquid crystal layer 32 is configured to reflect, of the incident light LTi which passed through the optical waveguide 1, invisible light LT4 of first circularly polarized light or second circularly polarized light.

For example, in the second liquid crystal layer 32, the helical structure 311 comprises a fourth helical pitch P4 so as to reflect invisible light LT41 of the first circularly polarized light. The fourth helical pitch P4 is different from each of the first helical pitch P1, the second helical pitch P2 and the third helical pitch P3 shown in FIG. 4, etc. When invisible light LT4 is ultraviolet light, the fourth helical pitch P4 is less than the first helical pitch P1. When invisible light LT4 is infrared light, the fourth helical pitch P4 is greater than the third helical pitch P3.

In this embodiment 3, the light LTr reflected on the optical element 3 includes the first, second and third components LT11, LT21 and LT31 of the first circularly polarized light reflected on the reflective surfaces 321 of the first liquid crystal layer 31, and invisible light LT41 of the first circularly polarized light reflected on the reflective surface 321 of the second liquid crystal layer 32. The light LTt which passes through the optical element 3 includes the first, second and third components LT12, LT22 and LT32 of the second circularly polarized light, and invisible light LT42.

In this embodiment 3, effects similar to those of embodiment 1 are obtained. Further, in addition to the light of substantially the entire wavelength range of visible light, invisible light can be introduced into a photovoltaic cell 5. Thus, the electric generation efficiency of the photovoltaic cell 5 can be further improved.

### Modified Example

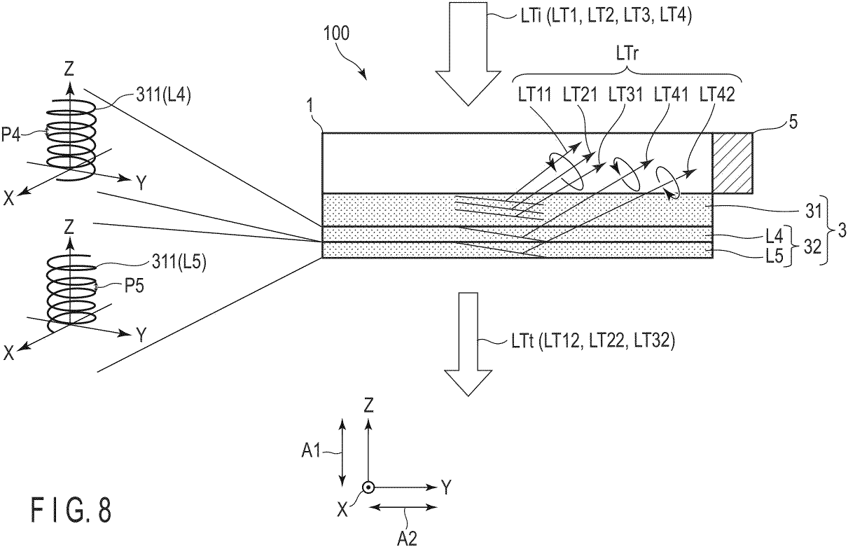

FIG. 8 is a cross-sectional view schematically showing the optical element 3 according to a modified example of embodiment 3. The modified example shown in FIG. 8 is different from the embodiment 3 shown in FIG. 7 in respect that the second liquid crystal layer 32 consists of a stacked layer body of a fourth layer L4 and a fifth layer L5.

In the second liquid crystal layer 32, each of the fourth layer L4 and the fifth layer L5 comprises cholesteric liquid crystals which twist in a single direction as the helical structures 311. Here, a cholesteric liquid crystal in each of the fourth layer L4 and the fifth layer L5 is schematically shown. In the fourth layer L4 and the fifth layer L5, the cholesteric liquid crystals twist in opposite directions. These fourth layer L4 and fifth layer L5 are configured to reflect invisible light LT4 of the incident light LTi which passed through the optical waveguide 1.

For example, in the fourth layer L4, the helical structure 311 comprises the fourth helical pitch P4 so as to reflect invisible light LT41 of the first circularly polarized light. In the fifth layer L5, the helical structure 311 comprises a fifth helical pitch P5 so as to reflect invisible light LT42 of the second circularly polarized light. The fourth helical pitch P4 and the fifth helical pitch P5 are substantially equal to each other.

The fourth helical pitch P4 and the fifth helical pitch P5 are different from each of the first helical pitch P1, the second helical pitch P2 and the third helical pitch P3 shown in FIG. 4, etc. When invisible light LT4 is ultraviolet light, the fourth helical pitch P4 and the fifth helical pitch P5 are less than the first helical pitch P1. When invisible light LT4 is infrared light, the fourth helical pitch P4 and the fifth helical pitch P5 are greater than the third helical pitch P3.

In this modified example, the light LTr reflected on the optical element 3 includes the first, second and third components LT11, LT21 and LT31 of the first circularly polarized light reflected on the reflective surfaces 321 of the first liquid crystal layer 31, invisible light LT41 of the first circularly polarized light reflected on the reflective surface 321 of the fourth layer L4 of the second liquid crystal layer 32, and invisible light LT42 of the second circularly polarized light reflected on the reflective surface 321 of the fifth layer L5. Thus, the light LTt which passes through the optical element 3 includes the first, second and third components LT12, LT22 and LT32 of the second circularly polarized light.

In this modified example, effects similar to those of embodiment 3 are obtained. In addition, the invisible light of the first circularly polarized light and the invisible light of the second circularly polarized light can be introduced into the photovoltaic cell 5. Thus, the electric generation efficiency of the photovoltaic cell 5 can be further improved.

In the embodiments 1 to 3 described above, the first liquid crystal layer 31 of the optical element 3 is configured to reflect one of the first circularly polarized light and the second circularly polarized light of at least part of a plurality of wavelength ranges. Further, the first liquid crystal layer 31 is configured to reflect one of the first circularly polarized light and the second circularly polarized light in at least two wavelength ranges of the first, second and third wavelength ranges described above.

### Embodiment 4

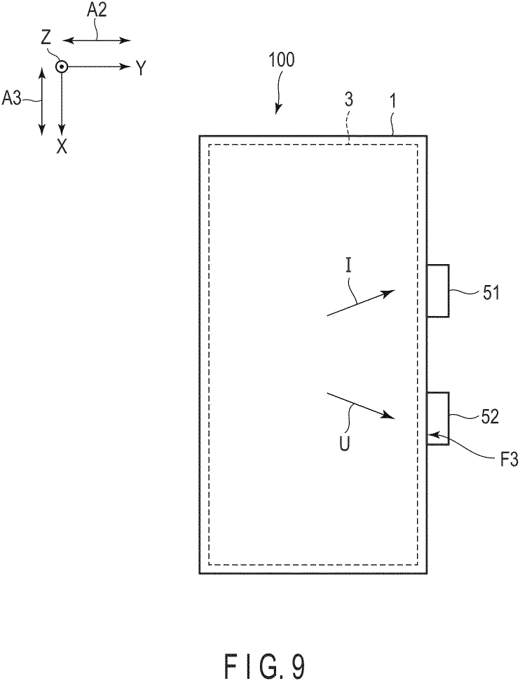

FIG. 9 is a plan view schematically showing a photovoltaic cell device 100 according to embodiment 4. The photovoltaic cell device 100 comprises an optical waveguide 1, an optical element 3, a first photovoltaic cell 51 and a second photovoltaic cell 52. Each of the first photovoltaic cell 51 and the second photovoltaic cell 52 is a silicon-based photovoltaic cell. It should be noted that the first photovoltaic cell 51 comprises polycrystalline silicon and the second photovoltaic cell 52 comprises amorphous silicon.

When polycrystalline silicon is compared with amorphous silicon, the peaks of the respective absorption wavelengths are different from each other. The peak of the absorption wavelength of amorphous silicon is approximately 450 nm. The peak of the absorption wavelength of polycrystalline silicon is approximately 700 nm. In other words, polycrystalline silicon has a higher absorptance for infrared light than amorphous silicon. Thus, the first photovoltaic cell 51 is suitable for electric generation by infrared light. Amorphous silicon has a higher absorptance for ultraviolet light than polycrystalline silicon. Thus, the second photovoltaic cell 52 is suitable for electric generation by ultraviolet light. It should be noted that the first photovoltaic cell 51 may be a compound-based photovoltaic cell and may be, for example, a gallium arsenide-based photovoltaic cell.

The first photovoltaic cell 51 and the second photovoltaic cell 52 face a side surface F3 at different positions. In the example shown in FIG. 9, the first photovoltaic cell 51 and the second photovoltaic cell 52 are arranged in a third direction A3.

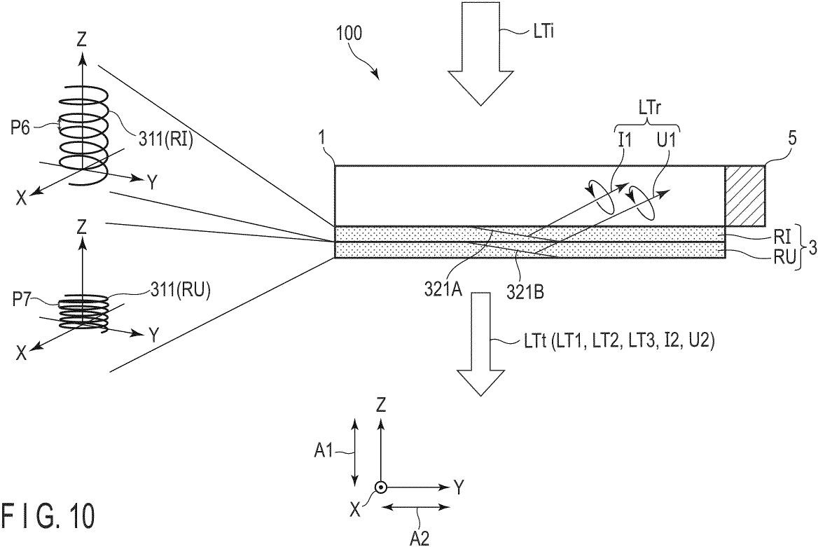

FIG. 10 is a cross-sectional view schematically showing the photovoltaic cell device 100 according to embodiment 4. Here, the illustrations of the first photovoltaic cell 51 and the second photovoltaic cell 52 are omitted.

The optical element 3 comprises an infrared reflective layer RI, and an ultraviolet reflective layer RU overlapping the infrared reflective layer RI. These infrared reflective layer RI and ultraviolet reflective layer RU are equivalent to the second liquid crystal layer 32 which is provided to reflect invisible light and is explained in embodiment 2 and embodiment 3. In the example of FIG. 10, the infrared reflective layer RI is provided between the optical waveguide 1 and the ultraviolet reflective layer RU. However, the ultraviolet reflective layer RU may be provided between the optical waveguide 1 and the infrared reflective layer RI.

Each of the infrared reflective layer RI and the ultraviolet reflective layer RU is a liquid crystal layer comprising cholesteric liquid crystals which twist in a single direction as helical structures 311. Here, a cholesteric liquid crystal in each of the infrared reflective layer RI and the ultraviolet reflective layer RU is schematically shown. In the infrared reflective layer RI and the ultraviolet reflective layer RU, the cholesteric liquid crystals twist in the same direction. However, they may twist in opposite directions.

For example, in the infrared reflective layer RI, the helical structure 311 comprises a sixth helical pitch P6 so as to reflect the infrared light I1 of first circularly polarized light. The sixth helical pitch P6 is greater than the third helical pitch P3 described above.

In the ultraviolet reflective layer RU, the helical structure 311 comprises a seventh helical pitch P7 so as to reflect the ultraviolet light U1 of the first circularly polarized light. The seventh helical pitch P7 is less than the first helical pitch P1 described above.

In this embodiment 4, the light LTr reflected on the optical element 3 includes the infrared light I1 of the first circularly polarized light reflected on the reflective surface 321A of the infrared reflective layer RI, and the ultraviolet light U1 of the first circularly polarized light reflected on the reflective surface 321B of the ultraviolet reflective layer RU. The light LTt which passes through the optical element 3 includes a first component LT1, a second component LT2 and a third component LT3, the infrared light I2 of second circularly polarized light, and ultraviolet light U2.

In this embodiment 4, as most of the visible light passes through the photovoltaic cell device 100, the coloring of the light which passes through the photovoltaic cell device 100 can be prevented. Further, infrared light and ultraviolet light as the invisible light of solar light can be used for electric generation.

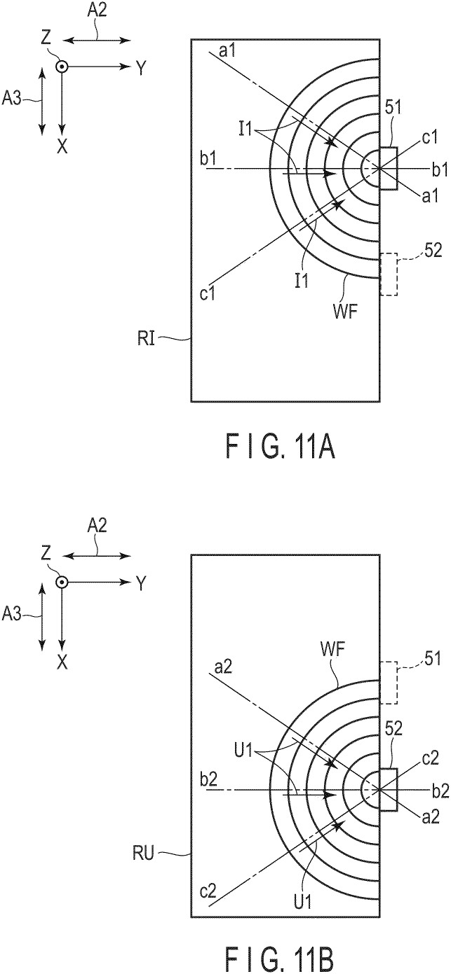

FIG. 11A is a plan view schematically showing an example of the infrared reflective layer RI which can be combined with the first photovoltaic cell 51 according to embodiment 4. The infrared reflective layer RI is configured to condense infrared light I1 toward the first photovoltaic cell 51. In order to facilitate understanding of propagation of the infrared light I1 reflected on the infrared reflective layer RI, FIG. 11A shows the wavefronts WF of infrared light I1.

In FIG. 11A, the section of the infrared reflective layer RI along the a1-a1 line, the section of the infrared reflective layer RI along the b1-b1 line and the section of the infrared reflective layer RI along the c1-c1 line are similar to the section of the first layer L1 shown in FIG. 2 or the section of the first layer L1 shown in FIG. 5.

In other words, the reflective surfaces 321A of the infrared reflective layer RI shown in FIG. 10 are inclined surfaces which incline so as to reflect infrared light I1 toward the first photovoltaic cell 51 at respective positions in an X-Y plane. The infrared light I1 reflected on the reflective surfaces 321A propagates through the optical waveguide 1 toward the first photovoltaic cell 51.

FIG. 11B is a plan view schematically showing an example of the ultraviolet reflective layer RU which can be combined with the second photovoltaic cell 52 according to embodiment 4. The ultraviolet reflective layer RU is configured to condense ultraviolet light U1 toward the second photovoltaic cell 52. FIG. 11B shows the wavefronts WF of the ultraviolet light U1 reflected on the ultraviolet reflective layer RU.

In FIG. 11B, the section of the ultraviolet reflective layer RU along the a2-a2 line, the section of the ultraviolet reflective layer RU along the b2-b2 line and the section of the ultraviolet reflective layer RU along the c2-c2 line are similar to the section of the first layer L1 shown in FIG. 2 or the section of the first layer L1 shown in FIG. 5.

In other words, the reflective surfaces 321B of the ultraviolet reflective layer RU shown in FIG. 10 are inclined surfaces which incline so as to reflect ultraviolet light U1 toward the second photovoltaic cell 52 at respective positions in the X-Y plane. The ultraviolet light U1 reflected on the reflective surfaces 321B propagates through the optical waveguide 1 toward the second photovoltaic cell 52.

Thus, as the reflective surfaces 321A of the infrared reflective layer RI are inclined surfaces different from the reflective surfaces 321B of the ultraviolet reflective layer RU, infrared light I1 propagates toward the first photovoltaic cell 51, and ultraviolet light U1 propagates toward the second photovoltaic cell 52. Thus, the amount of the received light of the first photovoltaic cell 51 and the second photovoltaic cell 52 per unit time can be increased. In this way, the electricity generated in the photovoltaic cell device 100 can be increased.

### Embodiment 5

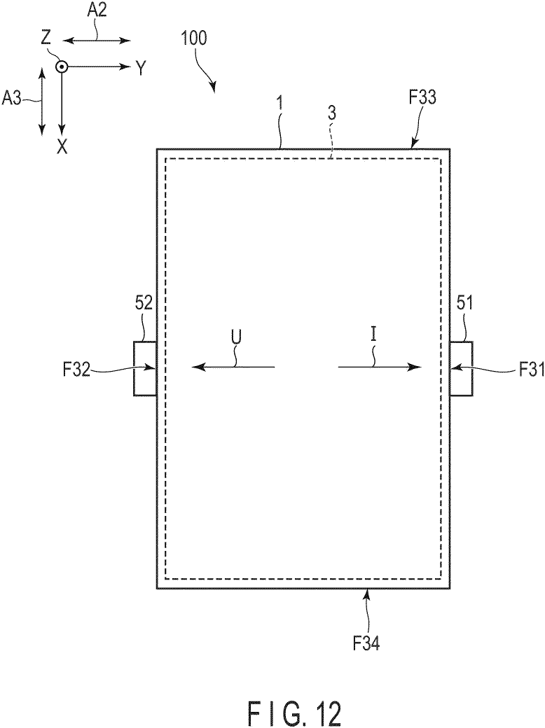

FIG. 12 is a plan view schematically showing a photovoltaic cell device 100 according to embodiment 5. The embodiment 5 shown in FIG. 12 is different from the embodiment 4 shown in FIG. 9 in respect that a first photovoltaic cell 51 faces a second photovoltaic cell 52 across an intervening optical waveguide 1 in a second direction A2. In the example shown in FIG. 12, of side surfaces F3, the first photovoltaic cell 51 faces a side surface F31 on the right side of the figure, and the second photovoltaic cell 52 faces a side surface F32 on the left side of the figure.

The first photovoltaic cell 51 may face the second photovoltaic cell 52 in a third direction A3. For example, the first photovoltaic cell 51 may face a side surface F33 and the second photovoltaic cell 52 may face a side surface F34. The first photovoltaic cell 51 may face the side surface F34 and the second photovoltaic cell 52 may face the side surface F33.

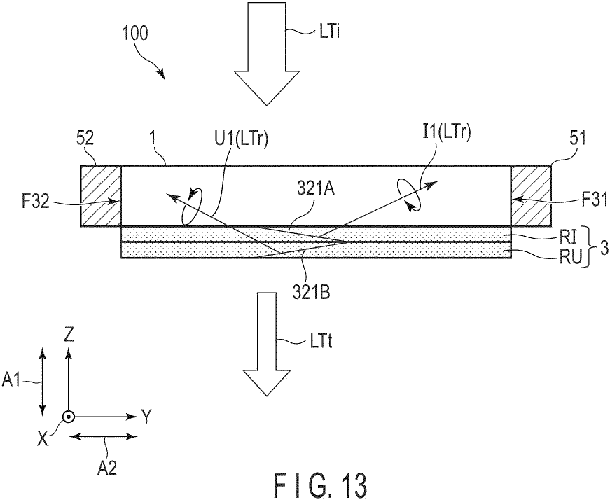

FIG. 13 is a cross-sectional view schematically showing the photovoltaic cell device 100 according to embodiment 5.

The reflective surface 321A of an infrared reflective layer RI is an inclined surface different from the reflective surface 321B of an ultraviolet reflective layer RU. In other words, the reflective surface 321A inclines so as to reflect, of the incident light LTi which passed through the optical waveguide 1, infrared light I1 toward the first photovoltaic cell 51. The reflective surface 321B inclines so as to reflect, of the incident light LTi which passed through the optical waveguide 1, ultraviolet light U1 toward the second photovoltaic cell 52.

In this embodiment 5, effects similar to those of the above embodiment 4 are obtained.

### Embodiment 6

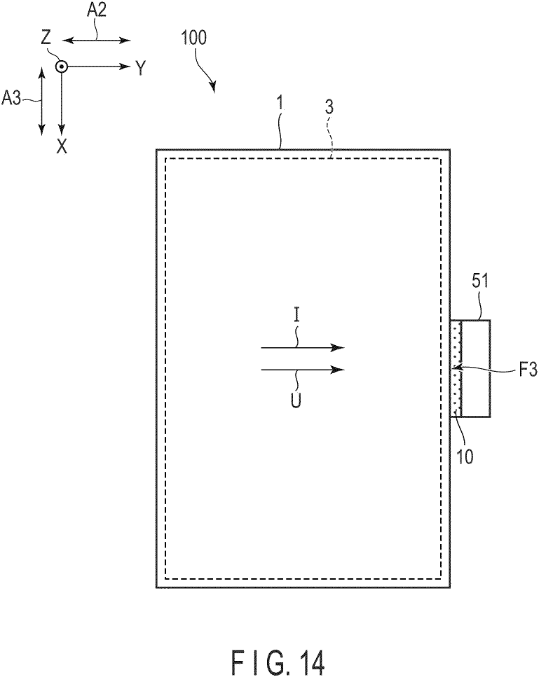

FIG. 14 is a plan view schematically showing a photovoltaic cell device 100 according to embodiment 6. The photovoltaic cell device 100 comprises an optical waveguide 1, an optical element 3, a first photovoltaic cell 51 and a phosphor layer 10. The first photovoltaic cell 51 is, for example, a silicon-based photovoltaic cell comprising polycrystalline silicon. However, the first photovoltaic cell 51 may be a compound-based photovoltaic cell such as a gallium arsenide-based photovoltaic cell. The phosphor layer 10 is a wavelength conversion layer which converts ultraviolet light U into infrared light I. The phosphor layer 10 is in contact with a side surface F3 and is provided between the optical waveguide 1 and the first photovoltaic cell 51.

The photovoltaic cell device 100 of embodiment 6 does not comprise the second photovoltaic cell 52 explained in the above embodiment 4 or 5.

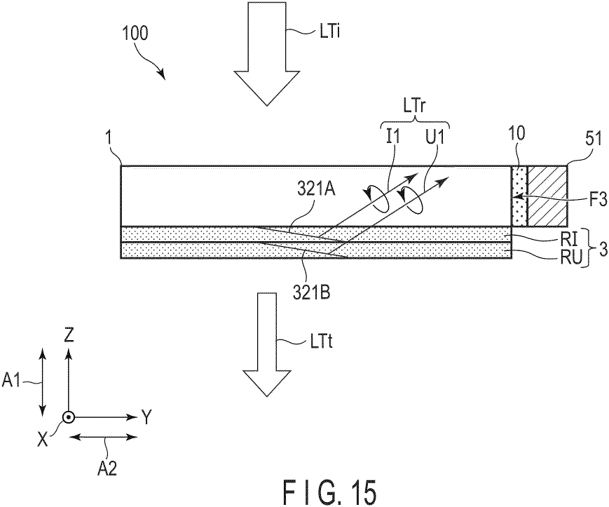

FIG. 15 is a cross-sectional view schematically showing the photovoltaic cell device 100 according to embodiment 6. The reflective surface 321A of an infrared reflective layer RI inclines so as to reflect, of the incident light LTi which passed through the optical waveguide 1, infrared light I1 toward the first photovoltaic cell 51. The reflective surface 321B of an ultraviolet reflective layer RU inclines so as to reflect, of the incident light LTi which passed through the optical waveguide 1, ultraviolet light U1 toward the first photovoltaic cell 51.

The infrared light I1 reflected on the reflective surface 321A propagates inside the optical waveguide 1, is emitted from the side surface F3, and subsequently, passes through the phosphor layer 10 and is received in the first photovoltaic cell 51. The ultraviolet light U1 reflected on the reflective surface 321B propagates inside the optical waveguide 1, is emitted from the side surface F3, and subsequently, is converted into infrared light in the phosphor layer 10 and is received in the first photovoltaic cell 51.

In this embodiment 6, in addition to the infrared light I1 reflected on the infrared reflective layer RI, the ultraviolet light U1 reflected on the ultraviolet reflective layer RU can be used for electric generation after it is converted into infrared light. In addition, compared to embodiments 4 and 5, as it is unnecessary to prepare different types of photovoltaic cells, the cost can be reduced.

### Modified Example 1

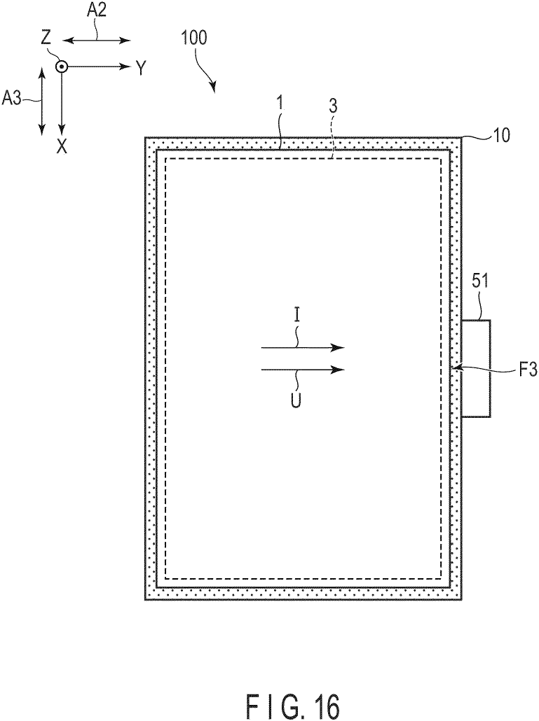

FIG. 16 is a plan view schematically showing the photovoltaic cell device 100 according to modified example 1 of embodiment 6. The modified example 1 shown in FIG. 16 is different from the embodiment 6 shown in FIG. 14 in respect that the phosphor layer 10 is provided for all of the side surfaces F3.

In this modified example 1, effects similar to those described above are obtained.

### Modified Example 2

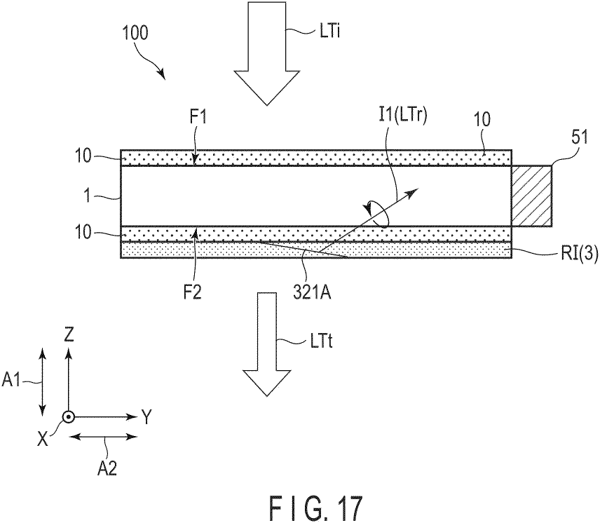

FIG. 17 is a plan view schematically showing the photovoltaic cell device 100 according to modified example 2 of embodiment 6. The modified example 2 shown in FIG. 17 is different from the embodiment 6 shown in FIG. 15 in respect that the phosphor layer 10 is provided over substantially the whole surfaces of a first main surface F1 and a second main surface F2. It should be noted that the phosphor layer 10 may be provided in one of the first main surface F1 and the second main surface F2. The phosphor layer 10 may be provided in all of the first main surface F1, the second main surface F2 and the side surfaces F3 so as to cover the entire optical waveguide 1.

In this modified example 2, ultraviolet light U is converted into infrared light I by the phosphor layer 10 provided in the first main surface F1 or the phosphor layer 10 provided in the second main surface F2. Thus, the optical element 3 can be configured as a single-layer body of the infrared reflective layer RI without comprising the ultraviolet reflective layer RU.

In this modified example 2, effects similar to those described above are obtained.

In the embodiments 4 to 6 described above, the optical element 3 may further comprise a first liquid crystal layer 31 which reflects visible light in a manner similar to that of embodiments 1 to 3.

Each of the infrared reflective layer RI and the ultraviolet reflective layer RU may be configured to reflect both the first circularly polarized light and the second circularly polarized light toward the optical waveguide 1. Specifically, in a manner similar to that of the embodiment 3 shown in FIG. 8, the infrared reflective layer RI should consist of a stacked layer body of at least two layers such that the cholesteric liquid crystal of one of the layers and the cholesteric liquid crystal of the other layer comprise substantially the same helical pitch and twist in opposite directions. The ultraviolet reflective layer RU may be configured in a manner similar to that of the infrared reflective layer RI.

Further, the embodiments 1 to 6 described above can be combined with each other as needed.

Each of the embodiments explained above can provide a photovoltaic cell device which can generate electricity without coloring.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photovoltaic cell device comprising:
an optical waveguide comprising a first main surface, a second main surface facing the first main surface, and a side surface;
an optical element facing the second main surface; and
a photovoltaic cell facing the side surface, wherein
the optical element comprises
a first liquid crystal layer which comprises a cholesteric liquid crystal, reflects, of visible light incident on the first main surface, circularly polarized light of one of first circularly polarized light and second circularly polarized light rotating in an opposite direction of the first circularly polarized light toward the optical waveguide and the photovoltaic cell, and transmits the other circularly polarized light,
the visible light includes a plurality of wavelength ranges, and
the first liquid crystal layer reflects one of the first circularly polarized light and the second circularly polarized light of part of the wavelength ranges.

2. The photovoltaic cell device of claim 1, wherein
the wavelength ranges include a first wavelength range, a second wavelength range different from the first wavelength range, and a third wavelength range different from the first wavelength range and the second wavelength range, and
the first liquid crystal layer reflects one of the first circularly polarized light and the second circularly polarized light in at least two wavelength ranges of the first, second and third wavelength ranges.

3. The photovoltaic cell device of claim 1, wherein
the wavelength ranges include a first wavelength range including a first component, a second wavelength range different from the first wavelength range and including a second component, and a third wavelength range different from the first wavelength range and the second wavelength range and including a third component.

4. The photovoltaic cell device of claim 3, wherein
the first component is a blue component, and the second component is a green component, and the third component is a red component.

5. The photovoltaic cell device of claim 4, wherein
the first liquid crystal layer comprises:
a first layer containing the cholesteric liquid crystal comprising a first helical pitch for reflecting the first component;
a second layer containing the cholesteric liquid crystal comprising a second helical pitch for reflecting the second component; and
a third layer containing the cholesteric liquid crystal comprising a third helical pitch for reflecting the third component.

6. The photovoltaic cell device of claim 4, wherein
in the first liquid crystal layer, a helical pitch of the cholesteric liquid crystal continuously changes, and
the cholesteric liquid crystal comprises:
a portion comprising a first helical pitch for reflecting the first component;
a portion comprising a second helical pitch for reflecting the second component; and
a portion comprising a third helical pitch for reflecting the third component.

7. The photovoltaic cell device of claim 4, wherein
the optical element comprises a second liquid crystal layer overlapping the first liquid crystal layer, and
the second liquid crystal layer comprises a cholesteric liquid crystal and reflects, of invisible light incident on the first main surface, circularly polarized light of at least one of the first circularly polarized light and the second circularly polarized light toward the optical waveguide and the photovoltaic cell.

8. The photovoltaic cell device of claim 7, wherein
the second liquid crystal layer comprises:
a fourth layer containing the cholesteric liquid crystal comprising a fourth helical pitch; and
a fifth layer containing the cholesteric liquid crystal comprising a fifth helical pitch,
the fourth helical pitch is equal to the fifth helical pitch, and
in the fourth layer and the fifth layer, the cholesteric liquid crystals twist in opposite directions.

9. The photovoltaic cell device of claim 7, wherein
the cholesteric liquid crystal of the second liquid crystal layer comprises a helical pitch less than a helical pitch for reflecting the first component.

10. The photovoltaic cell device of claim 7, wherein
the cholesteric liquid crystal of the second liquid crystal layer comprises a helical pitch greater than a helical pitch for reflecting the third component.

11. A photovoltaic cell device comprising:
an optical waveguide comprising a first main surface, a second main surface facing the first main surface, and a side surface;
an optical element facing the second main surface; and
a first photovoltaic cell facing the side surface and comprising polycrystalline silicon, wherein
the optical element comprises
an infrared reflective layer which comprises a cholesteric liquid crystal and reflects, of infrared light incident on the first main surface, at least one of first circularly polarized light and second circularly polarized light rotating in an opposite direction of the first circularly polarized light toward the optical waveguide and the first photovoltaic cell.

12. The photovoltaic cell device of claim 11, further comprising a second photovoltaic cell which faces the side surface at a position different from the first photovoltaic cell and comprises amorphous silicon, wherein
the optical element comprises
an ultraviolet reflective layer which overlaps the infrared reflective layer, comprises a cholesteric liquid crystal, and reflects, of ultraviolet light incident on the first main surface, at least one of the first circularly polarized light and the second circularly polarized light toward the optical waveguide and the second photovoltaic cell.

13. The photovoltaic cell device of claim 12, wherein
a reflective surface of the infrared reflective layer is an inclined surface different from a reflective surface of the ultraviolet reflective layer.

14. The photovoltaic cell device of claim 11, wherein
the optical waveguide comprises a phosphor layer which converts incident ultraviolet light into infrared light, and
the phosphor layer is provided in at least one of the first main surface, the second main surface and the side surface.
